(19) United States
(12) Patent Application Publication
(10) Pub. No.: US 2025/0294992 A1
(43) Pub. Date: Sep. 18, 2025

(54) SELF-MASK FOR SQUARE AND PENTILE UNIT PIXEL ARRAYS

(71) Applicant: Applied Materials, Inc., Santa Clara, CA (US)

(72) Inventors: Jong Yun KIM, Hwaseong (KR); Ji Young CHOUNG, Hwaseong-si (KR); Kim Seong SIM, Singapore (SG); Yu-Hsin LIN, Zhubei City (TW)

(21) Appl. No.: 19/050,194

(22) Filed: Feb. 11, 2025

Related U.S. Application Data
(60) Provisional application No. 63/565,694, filed on Mar. 15, 2024.

(51) Int. Cl. H10K 59/35; H10K 59/12; H10K 59/122

(52) U.S. Cl. CPC H10K 59/353; H10K 59/1201; H10K 59/122; H10K 59/351

(57) ABSTRACT

Embodiments of the present disclosure provide methods for forming pinwheel shaped self-masks. The method includes constructing an RGB matrix, forming dielectrics which divide the RGB matrix into a plurality of square unit pixels, forming a first color pixel in each of the plurality of square unit pixels by using a first evaporation source, forming a second color pixel in each of the plurality of square unit pixels by using a second evaporation source, forming a third color pixel in each of the plurality of square unit pixels by using a third evaporation source, and forming a fourth color pixel in each of the plurality of square unit pixels by using the third evaporation source, the fourth color pixel being a same color as the third color pixel. In another embodiment, a PenTile matrix is constructed to divide the PenTile matrix into a plurality of diamond unit pixels.

### CROSS-REFERENCE TO RELATED APPLICATIONS

This application claims priority to U.S. Provisional Application No. 63/565,694, filed Mar. 15, 2024, the entire disclosure of which is hereby incorporated by reference herein.

### BACKGROUND

### Field

Embodiments described herein generally relate to a display. More specifically, embodiments described herein relate to pixel arrays and methods of forming pixel arrays that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. OLED devices include a plurality of sub-pixels (e.g., a sub-pixel circuit) defined by adjacent pixel-defining layer (PDL) structures. Each sub-pixel has an anode, OLED material disposed on the anode, and a cathode disposed on the OLED material. Many augmented, virtual, and mixed reality applications require the use of OLED devices with a high pixel density. However, current fine metal mask (FMM) and lithography technology may not be suitable for forming OLED devices with a high pixel density.

Accordingly, what is needed in the art are improved sub-pixel arrays with increased pixel density and improved OLED performance and methods of forming the same.

### SUMMARY

Embodiments of the present disclosure provide a method including constructing an RGB matrix, forming dielectrics which divide the RGB matrix into a plurality of square unit pixels, forming a first color pixel in each of the plurality of square unit pixels by using a first evaporation source, forming a second color pixel in each of the plurality of square unit pixels by using a second evaporation source, forming a third color pixel in each of the plurality of square unit pixels by using a third evaporation source, and forming a fourth color pixel in each of the plurality of square unit pixels by using the third evaporation source, the fourth color pixel being a same color as the third color pixel.

Embodiments of the present disclosure provide a method including constructing an RGB matrix, dividing the RGB matrix into a plurality of square unit pixels by forming dielectric walls within the RGB matrix, forming a first color pixel in each of the plurality of square unit pixels by using a first evaporation source at a first corner of the RGB matrix, forming a second color pixel in each of the plurality of square unit pixels by using a second evaporation source at a second corner of the RGB matrix, and forming a third color pixel in each of the plurality of square unit pixels by using a third evaporation source at a side of the RGB matrix such that the third color pixel is twice a size of the first color pixel and twice a size of the second color pixel.

Embodiments of the present disclosure provide for a sub-pixel circuit including a plurality of square unit pixels, each of the plurality of square unit pixels including dielectric walls disposed therearound to form multiple pinwheel shapes, a first color pixel formed in each of the plurality of square unit pixels using a first evaporation source, a second color pixel formed in each of the plurality of square unit pixels using a second evaporation source, and a third color pixel formed in each of the plurality of square unit pixels using a third evaporation source.

Embodiments of the present disclosure provide for a sub-pixel circuit including a plurality of diamond unit pixels, each of the plurality of diamond unit pixels including dielectric walls disposed therearound to form multiple pinwheel shapes, a first color pixel formed in each of the plurality of diamond unit pixels using a first evaporation source, a second color pixel formed in each of the plurality of diamond unit pixels using a second evaporation source, a third color pixel formed in each of the plurality of diamond unit pixels using a third evaporation source, and a fourth color pixel formed in each of the plurality of diamond unit pixels using the third evaporation source, the fourth color pixel being a same color as the third color pixel.

Embodiments of the present disclosure provide a method including constructing a PenTile matrix, forming dielectrics which divide the PenTile matrix into a plurality of diamond unit pixels, forming a first color pixel in each of the plurality of diamond unit pixels by using a first evaporation source, forming a second color pixel in each of the plurality of diamond unit pixels by using a second evaporation source, forming a third color pixel in each of the plurality of diamond unit pixels by using a third evaporation source, and forming a fourth color pixel in each of the plurality of diamond unit pixels by using the third evaporation source, the fourth color pixel being a same color as the third color pixel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, top-view of a square unit pixel, with a first deposition resulting in a first shaded area covering ½ of the square unit pixel, according to one or more of the embodiments described herein.

FIG. 1B is a schematic, top-view of a square unit pixel, with a second deposition resulting in a second shaded area covering ¾ of the square unit pixel, according to one or more of the embodiments described herein.

FIG. 2A is a schematic, perspective view of a square unit pixel, with the second deposition resulting in the second shaded area covering ¾ of the square unit pixel, according to one or more of the embodiments described herein.

FIG. 2B is a schematic, perspective view of a square unit pixel, with the first deposition resulting in the first shaded area covering ½ of the square unit pixel, according to one or more of the embodiments described herein.

FIG. 3A is a schematic, top-view of an S-stripe or RGB pixel array, according to one or more of the embodiments described herein.

FIG. 3B is a schematic, top-view of the RGB pixel array where dielectric walls are formed to divide the RGB pixel array into multiple square unit pixels, according to one or more of the embodiments described herein.

FIG. 3C is a schematic, perspective view of the RGB pixel array where a first evaporation source is used from a first direction to create a first color pixel, according to one or more of the embodiments described herein.

FIG. 3D is a schematic, perspective view of the RGB pixel array where a second evaporation source is used from a second direction to create a second color pixel, according to one or more of the embodiments described herein.

FIG. 3E is a schematic, perspective view of the RGB pixel array where a third evaporation source is used from a third and fourth direction to create a third color pixel, according to one or more of the embodiments described herein.

FIG. 4 is a schematic, perspective view of the RGB pixel array where the third evaporation source is used from a fifth direction to create a fifth color pixel, according to one or more of the embodiments described herein.

FIG. 5A is a schematic, top-view of a PenTile diamond pixel array, according to one or more of the embodiments described herein.

FIG. 5B is a schematic, top-view of the PenTile diamond pixel array where dielectric walls are formed to divide the PenTile diamond pixel array into multiple diamond unit pixels, according to one or more of the embodiments described herein.

FIG. 5C is a schematic, perspective view of the PenTile diamond pixel array where a first evaporation source is used from a first direction to create a first color pixel, according to one or more of the embodiments described herein.

FIG. 5D is a schematic, perspective view of the PenTile diamond pixel array where a second evaporation source is used from a second direction to create a second color pixel, according to one or more of the embodiments described herein.

FIG. 5E is a schematic, perspective view of the PenTile diamond pixel array where a third evaporation source is used from a third direction to create a third color pixel, according to one or more of the embodiments described herein.

FIG. 5F is a schematic, perspective view of the PenTile diamond pixel array where a fourth evaporation source is used from a fourth direction to create a fourth color pixel, according to one or more of the embodiments described herein.

FIG. 6 is a method for using walls to divide an RGB matrix into square unit pixels each having 4 sub-pixels, according to one or more of the embodiments described herein.

FIG. 7 is a method for using walls to divide an RGB matrix into square unit pixels each having 3 sub-pixels according to one or more of the embodiments described herein.

FIG. 8 is a method for using walls to divide a PenTile matrix into diamond unit pixels each having 4 sub-pixels, where two of the sub-pixels are diamond shaped, according to one or more of the embodiments described herein.

FIGS. 9A-9F illustrate a cross-sectional view of a sub-pixel circuit for the RGB pixel array, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a display that includes organic light emitting diodes (OLEDs) and methods of forming the same. More specifically, embodiments provided herein generally relate to self-mask designs and methods of forming self-mask designs that may be utilized in OLED displays. The OLED displays disclosed herein may be used in any device that includes a display, including augmented, virtual, and mixed reality devices, as well as other devices with displays, including mobile phones and televisions.

In embodiments, self-mask designs are presented for square unit pixels and for PenTile unit pixels. When constructing OLEDs or micro-OLEDs, one sub-pixel array commonly used is the RGB array or RGB matrix or RGB stripe. One example embodiment relates to an RGB array, and, in particular, to a self-mask design for RGB arrays. When constructing OLEDs or micro-OLEDs, another sub-pixel array commonly used is the PenTile array or PenTile matrix. Another example embodiment relates to a PenTile array, and, in particular, to a self-mask design for PenTile arrays. Each unit pixel, whether square or diamond, includes a number of pixels or sub-pixels. In one example, each unit pixel, whether square or diamond, includes 4 sub-pixels. The square unit pixels each include 4 circular or oval sub-pixels and the diamond unit pixels each include 2 diamond sub-pixels and 2 circular or oval sub-pixels. Each sub-pixel may have the OLED material configured to emit a red, green, blue or other color light when energized. For example, the OLED material of a first sub-pixel emits a red light when energized, the OLED material of a second sub-pixel emits a green light when energized, and the OLED material of a third sub-pixel and a fourth sub-pixel emits a blue light when energized.

Each unit pixel or unit cell may be partially surrounded by a number of walls, the walls partially separating adjacent unit pixels and forming a number of openings or gaps between adjacent unit pixels. The shape and/or curves of the walls may be manipulated to enable the formation of desired unit pixels. In some embodiments, the one or more walls may include walls having different shapes and/or curves. The openings or gaps between adjacent walls allow current to pass through the unit pixels.

In addition, the unit pixels may be formed using oblique deposition for emission material layer (EML) deposition for red, green, and blue colors. The deposition process may include an evaporation process. As a result, the thickness of the deposited OLED material may not increase material consumption. Further, the angle of deposition (which includes an emission angle and an evaporation angle) used during the deposition of the OLED material may be carefully controlled during formation of the sub-pixels in the unit pixels. Controlling the angle of deposition results in a more stable open area (e.g., the area where the OLED material is deposited) and shadow area (e.g., the area where the OLED material is not deposited as a result of the walls) formation.

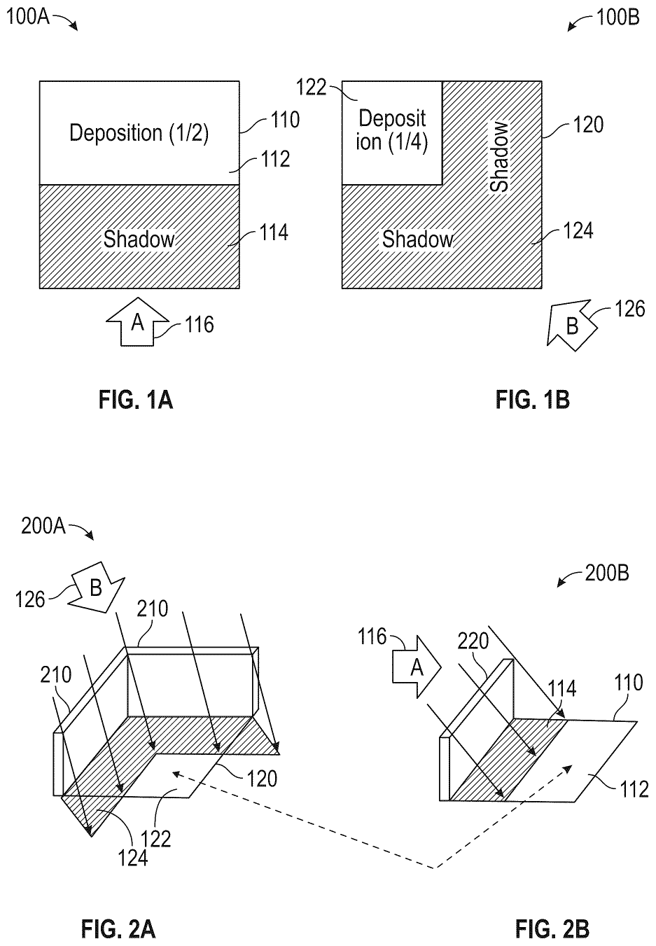

FIG. 1A is a schematic, top-view 100A of a square unit pixel, with a first deposition resulting in a first shaded area covering ½ of the square unit pixel, according to one or more of the embodiments described herein.

The unit pixel 110 is a square. The unit pixel 110 can include a plurality of pixels. In one example, the unit pixel 110 includes 4 pixels or sub-pixels operable to emit light. The unit pixel 110 may also be referred to as a unit cell.

An OLED material is deposited on one or more pixels in a first direction or at a first orientation designated by direction A. The deposition may be an oblique deposition. The deposition process may include an evaporation process. The evaporation process may include using or actuating a first evaporation source 116. The first evaporation source 116 can also be referred to as an evaporation deposition source. The first evaporation source 116 has a same orientation as the first orientation designated by direction A.

The thickness of the deposited OLED material may not increase material consumption. Further, the angle of deposition (which includes an emission angle and an evaporation angle) used during the deposition of the OLED material may be carefully controlled during formation of the pixels. Controlling the angle of deposition results in a more stable open area (e.g., the area where the OLED material is deposited) and shadow area (e.g., the area where the OLED material is not deposited as a result of the walls) formation. The first evaporation source 116 deposits OLED material such that an open area or deposition area 112 is formed. Further, the first evaporation source 116 deposits OLED material such that a shadow area 114 is formed. The deposition area 112 occupies ½ of the unit pixel 110 and the shadow area 114 occupies the other ½ of the unit pixel 110. The first evaporation source 116 is actuated from a side of the unit pixel 110.

FIG. 1B is a schematic, top-view 100B of a square unit pixel, with a second deposition resulting in a second shaded area covering ¾ of the square unit pixel, according to one or more of the embodiments described herein.

The unit pixel 120 is a square. The unit pixel 120 can include a plurality of pixels. In one example, the unit pixel 120 includes 4 pixels or sub-pixels operable to emit light. The unit pixel 120 may also be referred to as a unit cell.

An OLED material is deposited on one or more pixels in a second direction or at a second orientation designated by direction B. The deposition may be an oblique deposition. The deposition process may include an evaporation process. The evaporation process may include using or actuating a second evaporation source 126. The second evaporation source 126 can also be referred to as an evaporation deposition source. The second evaporation source 126 has a same orientation as the second orientation designated by direction B.

As noted above, controlling the angle of deposition results in a more stable open area (e.g., the area where the OLED material is deposited) and shadow area (e.g., the area where the OLED material is not deposited as a result of the walls) formation. The second evaporation source 126 deposits OLED material such that an open area or deposition area 122 is formed. Further, the second evaporation source 126 deposits OLED material such that a shadow area 124 is formed. The deposition area 122 occupies ¼ of the unit pixel 120 and the shadow area 124 occupies the other ¾ of the unit pixel 120. The second evaporation source 126 is actuated from a corner of the unit pixel 120.

FIG. 2A is a schematic, perspective view 200A of a square unit pixel, with the second deposition resulting in the second shaded area covering ¾ of the square unit pixel, according to one or more of the embodiments described herein.

In a 3D view of FIG. 1B, the walls 210 are shown. The walls 210 may also be referred to as self-mask walls or dielectric walls. The walls 210 are arranged on the boundaries between adjacent unit pixels 120. The walls 210 are rectangular shaped walls. The walls 210 may be other various shapes and/or may include various curves. The shape and/or curves of the walls 210 may be manipulated to enable the formation of desired sub-pixel arrays. In some embodiments, the walls 210 may include walls having different shapes and/or curves. The walls 210 have an aspect ratio of a height to a width.

When the second evaporation source 126 is oriented in a second orientation designated by direction B, the walls 210 provide for a shadowing effect during evaporation deposition of the OLED material with the evaporation angle set by the second evaporation source 126. In order to deposit at a particular angle, the second evaporation source 126 is configured to emit the OLED material at a particular angle with regard to the walls 210. By adjusting the angle of deposition by manipulating the orientation of the second evaporation source 126, the second evaporation source 126 can deposit the OLED material at different angles to adjust where the OLED material is disposed on the unit pixel 120. The oblique deposition is performed from a corner of the unit pixel 120.

The walls 210 define the boundaries of the open area or deposition area 122 and the shadow area 124. The second orientation, designated by direction B, of the second evaporation source 126 results in the deposition area 122 occupying ¼ of the unit pixel 120 and the shadow area 124 occupying the other ¾ of the unit pixel 120, as shown in FIG. 1B.

In some embodiments, the evaporation deposition process used to deposit the OLED material may include multiple sub-operations, and the second evaporation source 126 may be oriented differently during various sub-operations of operation to deposit the OLED material in each of the unit pixels in a desired location.

The OLED material is configured to emit a red, green, blue or other color light when energized.

FIG. 2B is a schematic, perspective view 200B of a square unit pixel, with the first deposition resulting in the first shaded area covering ½ of the square unit pixel, according to one or more of the embodiments described herein.

In a 3D view of FIG. 1A, the walls 220 are shown. The walls 220 may also be referred to as self-mask walls or dielectric walls. The walls 220 are arranged on the boundaries between adjacent unit pixels 110. The walls 220 are rectangular shaped walls. The walls 220 may be other various shapes and/or may include various curves. The shape and/or curves of the walls 220 may be manipulated to enable the formation of desired sub-pixel arrays. In some embodiments, the walls 220 may include walls having different shapes and/or curves. The walls 220 have an aspect ratio of a height to a width.

When the evaporation source is oriented in a first orientation designated by direction A, the walls 220 provide for a shadowing effect during evaporation deposition of the OLED material with the evaporation angle set by the first evaporation source 116. In order to deposit at a particular angle, the first evaporation source 116 is configured to emit the OLED material at a particular angle with regard to the walls 220. By adjusting the angle of deposition by manipulating the orientation of the first evaporation source 116, the first evaporation source 116 can deposit the OLED material at different angles to adjust where the OLED material is disposed on the unit pixel 110. The oblique deposition is performed from a side of the unit pixel 110.

The walls 220 define the boundaries of the open area or deposition area 112 and the shadow area 114. The first orientation, designated by direction A, of the first evaporation source 116 results in the deposition area 112 occupying ½ of the unit pixel 110 and the shadow area 114 occupying the other ½ of the unit pixel 110, as shown in FIG. 1A.

In some embodiments, the evaporation deposition process used to deposit the OLED material may include multiple sub-operations, and the first evaporation source 116 may be oriented differently during various sub-operations of operation to deposit the OLED material in each of the unit pixels in a desired location.

The OLED material is configured to emit a red, green, blue or other color light when energized.

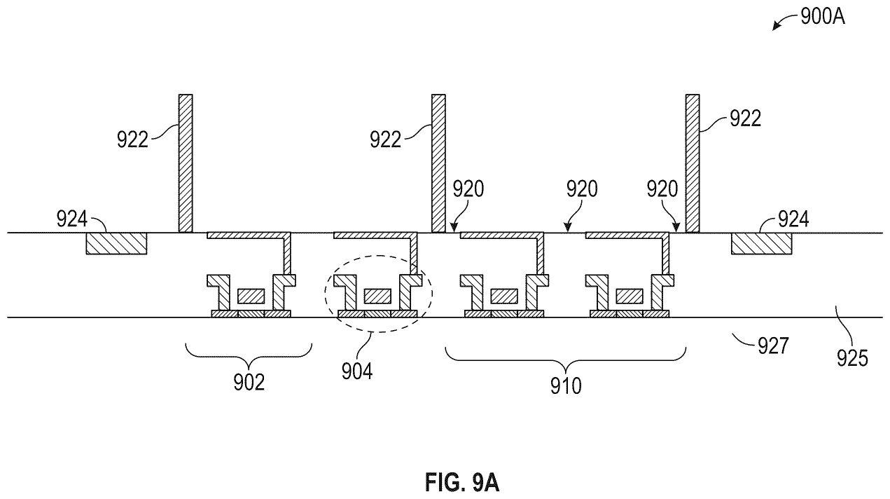

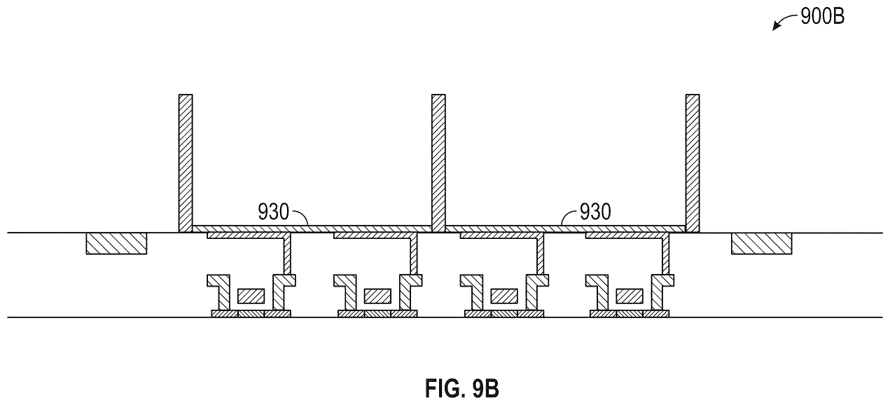

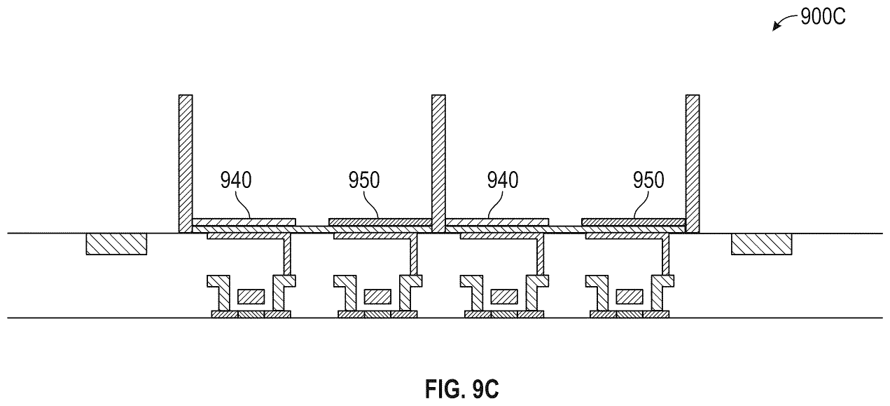

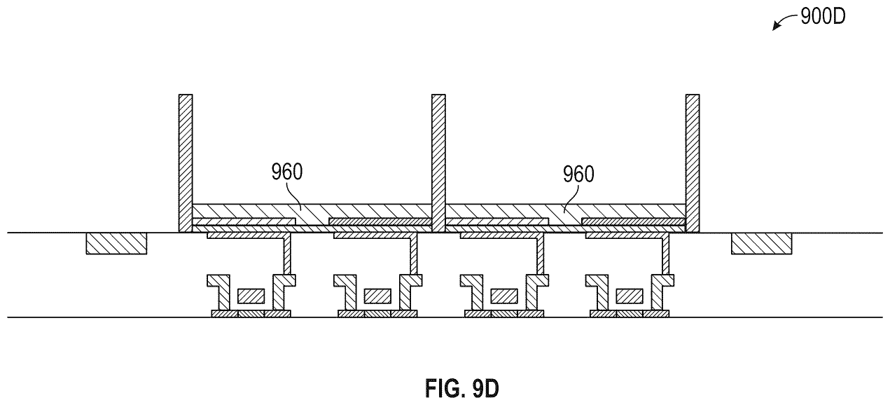

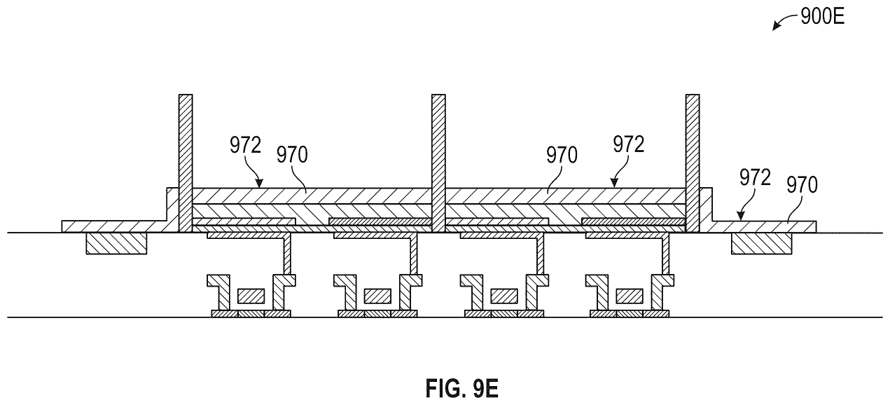

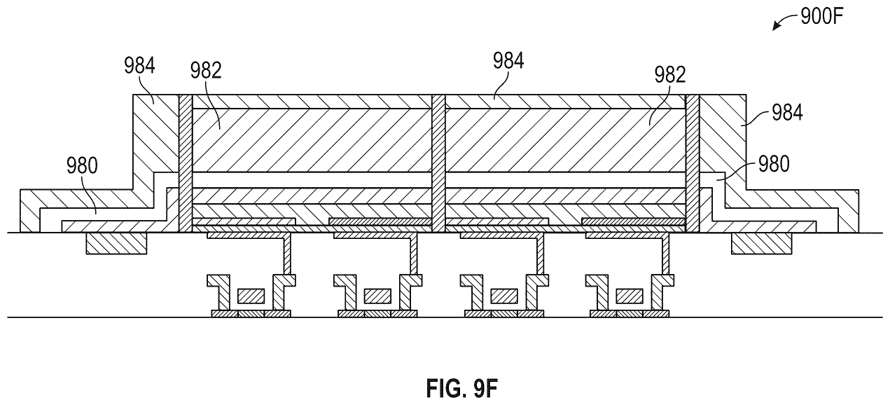

Regarding FIGS. 1A-2B, a sub-pixel circuit (FIGS. 9A-9F) is operable to activate each unit pixel 110, 120 individually and independently. In some embodiments, the sub-pixels in each of the unit pixels 110, 120 are mono-colored. In other embodiments, each of the sub-pixels in the unit pixels 110, 120 are operable to emit a different colored light.

Regarding FIGS. 1A-2B, for a square unit pixel, a half or three quarters of the square unit pixel area is shaded or shadowed by oblique deposition depending on the direction or orientation of the evaporation source. As such, the different shadowed areas of the unit pixel area can be provided based on oblique deposition from corners or sides of the square unit pixel. Oblique deposition from a corner can cause a ¾ shadowed area, whereas oblique deposition from a side can cause a ½ shadowed area.

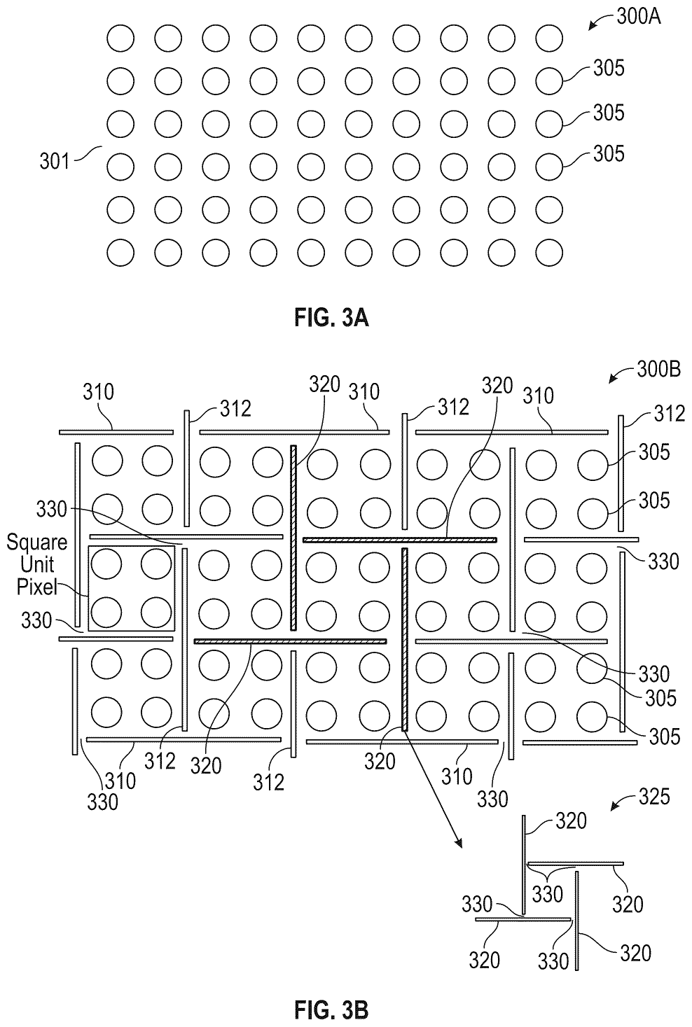

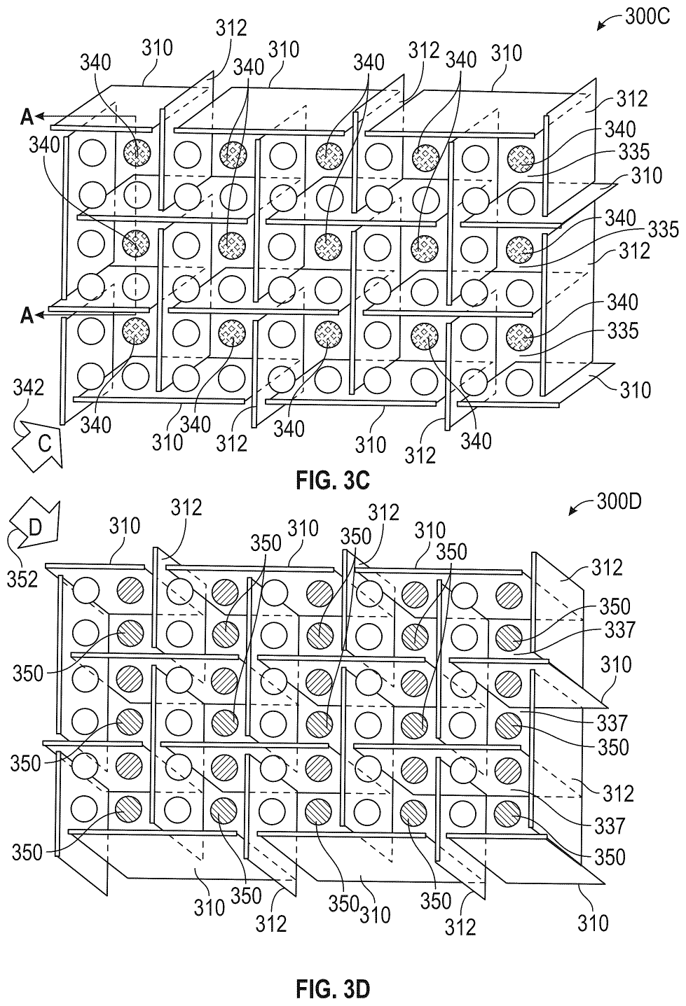

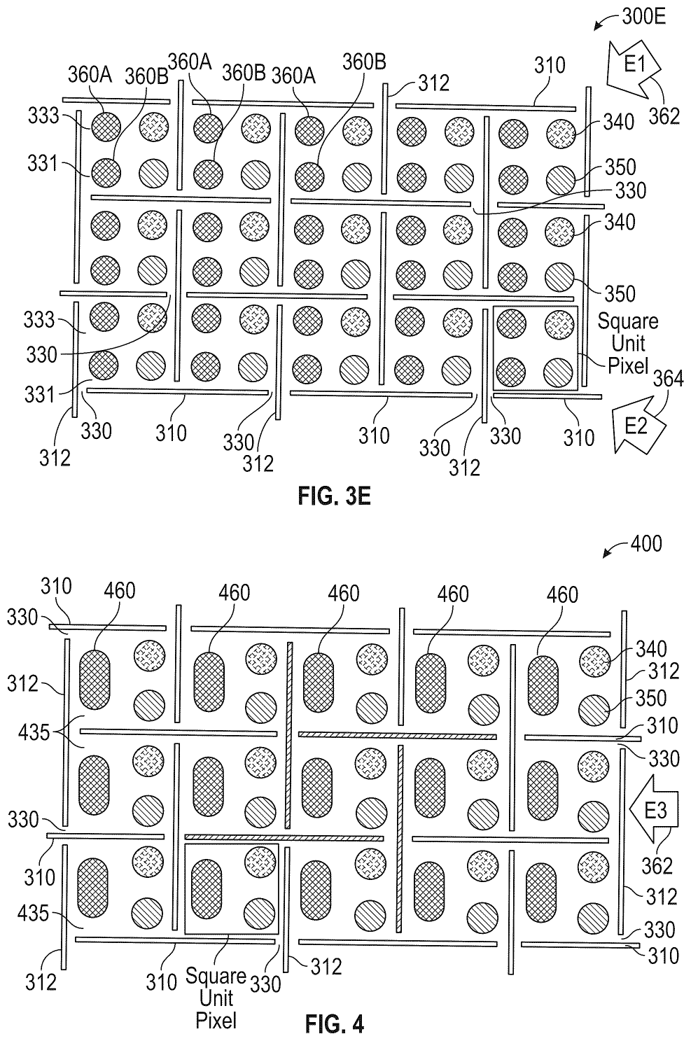

FIG. 3A is a schematic, top-view 300A of an S-stripe or RGB pixel array, according to one or more of the embodiments described herein.

The array 301 includes a plurality of pixels 305. The array 301 is configured to be a square or rectangular array. The plurality of pixels 305 are shown as circles or ovals. The array 301 can be an RGB matrix. RGB refers to a system representing the colors used on a digital display screen. Red, green, and blue can be combined in various proportions to obtain any color in the visible spectrum. When constructing OLEDs or micro-OLEDs, one sub-pixel array commonly used is the RGB array or RGB matrix or RGB stripe. FIGS. 3A-3E relate to an RGB array, and, in particular, to a self-mask design for RGB arrays.

FIG. 3B is a schematic, top-view 300B of the RGB pixel array where dielectric walls are formed to divide the RGB pixel array into multiple square unit pixels, according to one or more of the embodiments described herein.

The array 301 is divided into a plurality of unit pixels. Each unit pixel includes, e.g., 4 pixels or sub-pixels. The 4 sub-pixels are arranged in a square array. The array 301 is divided by strategically placing walls or dielectric walls or self-mask walls adjacent the pixels 305. Two types of walls are placed or disposed or formed. The first walls 310 are horizontal walls and the second walls 312 are vertical walls. The first walls 310 and the second walls 312 do not contact or intersect each other. Openings 330 are formed at the ends of the first walls 310 and the second walls 312. The openings 330 can also be referred to as gaps. The openings 330 allow for current to flow through the unit pixels to activate the plurality of pixels 305. The first walls 310 and the second walls 312 may partially surround each unit pixel, leavings the openings 330 between adjacent walls.

Current flows through the openings 330 of the unit pixels, which permits a continuous current path through a cathode 970 of a sub-pixel circuit (FIGS. 9A-9F). The current flows to the cathode disposed along the sub-pixel circuit to the bus-bars 924. Thus, current is operable to flow through the sub-pixel circuit. The current also flows from the cathode to the OLED material and into metal layers (not shown) of the sub-pixel circuit. The current activates sub-pixels within the unit pixels.

A portion of the first walls 310 and a portion of the second walls 312 can collectively form a pinwheel configuration 325. For example, wall portions 320 form the pinwheel configuration 325. The pinwheel configuration 325 includes two horizontal walls and two vertical walls. The two horizontal walls and the two vertical walls are separated from each other by the openings 330. The two horizontal walls do not contact the two vertical walls. The pinwheel configuration 325 defines a centrally disposed unit pixel with 4 sub-pixels. The array 301 can be divided to define a plurality of pinwheel configurations. As such, the pinwheel configuration 325 includes four walls or four dielectric walls separated by predefined openings or gaps between them to provide for uniform cathode current flow. The pinwheel configuration 325 can also be referred to as a pinwheel shaped self-mask.

In one example, a length of the first walls 310 is equal to a length of the second walls 312. The equal length of the first walls 310 and the second walls 312 creates the square unit pixels.

FIG. 3C is a schematic, perspective view 3000 of the RGB pixel array where a first evaporation source is used from a first direction to create a first color pixel, according to one or more of the embodiments described herein.

The first evaporation source 342 is positioned at a bottom corner (direction or orientation C) of the array 301 such that ¾ of each square unit pixel is shadowed. This results in a ¼ area of each square unit pixel that is exposed. The exposed area 335 of each square unit pixel is configured to receive OLED material to create a first color pixel 340. In one example, the first color pixel 340 is red. As such, one red sub-pixel is formed in each square unit pixel. Since there are multiple square unit pixels, there are multiple red sub-pixels within the array 301. Of course, in other examples, the color of the pixel may be green or blue.

The red sub-pixels of each of the square unit pixels are horizontally aligned with respect to each other. Further, the red sub-pixels of each of the square unit pixels are vertically aligned with respect to each other. Each red sub-pixel is equally spaced apart with respect to adjacent red sub-pixels.

FIG. 3D is a schematic, perspective view 300D of the RGB pixel array where a second evaporation source is used from a second direction to create a second color pixel, according to one or more of the embodiments described herein.

The second evaporation source 352 is positioned at a top corner (direction or orientation D) of the array 301 such that ¾ of each square unit pixel is shadowed. This results in a ¼ area of each square unit pixel that is exposed. The exposed area 337 of each square unit pixel is configured to receive OLED material to create a second color pixel 350. In one example, the second color pixel 350 is green. As such, one green sub-pixel is formed in each square unit pixel. Since there are multiple square unit pixels, there are multiple green sub-pixels within the array 301. Of course, in other examples, the color of the pixel may be red or blue.

The green sub-pixels of each of the square unit pixels are horizontally aligned with respect to each other. Further, the green sub-pixels of each of the square unit pixels are vertically aligned with respect to each other. Each green sub-pixel is equally spaced apart with respect to adjacent green sub-pixels.

The second color pixels 350 are positioned adjacent respective first color pixels 340. In one instance, the first color pixels occupy a top right space or area and the second color pixels occupy a bottom right space or area. Each square unit pixel includes one first color pixel 340 and one second color pixel 350.

FIG. 3E is a schematic, perspective view 300E of the RGB pixel array where a third evaporation source is used from a third and fourth direction to create a third color pixel, according to one or more of the embodiments described herein.

The third evaporation source 362 is positioned at a top corner (direction or orientation E₁) of the array 301 such that ¾ of each square unit pixel is shadowed. This results in a ¼ area of each square unit pixel that is exposed. The exposed area 331 of each square unit pixel is configured to receive OLED material to create a third color pixel 360B. In one example, the third color pixel 360B is blue.

The fourth evaporation source 364 is positioned at a bottom corner (direction or orientation E₂) of the array 301 such that ¾ of each square unit pixel is shadowed. This results in a ¼ area of each square unit pixel that is exposed. The exposed area 333 of each square unit pixel is configured to receive OLED material to create a fourth color pixel 360A. In one example, the fourth color pixel 360A is also blue.

The third color pixel 360B is vertically aligned with the fourth color pixel 360A within each of the square unit pixels. The third color pixel 360B is horizontally aligned with the other third color pixels 360B of horizontal square unit pixels. The fourth color pixel 360A is horizontally aligned with the other fourth color pixels 360A of horizontal square unit pixels. Similarly, the third color pixel 360B is vertically aligned with the other third color pixels 360B of vertical square unit pixels. The fourth color pixel 360A is vertically aligned with the other fourth color pixels 360A of vertical square unit pixels.

As such, two blue sub-pixels are formed in each square unit pixel. Since there are multiple square unit pixels, there are multiple blue sub-pixels within the array 301. Of course, in other examples, the color of the two pixels within each square unit pixel may be red or green.

Therefore, each square unit pixel includes four sub-pixels. The first sub-pixel is a red sub-pixel, the second sub-pixel is a green sub-pixel, the third sub-pixel is a blue sub-pixel, and the fourth sub-pixel is also a blue sub-pixel. In one example, the red sub-pixel can occupy a top right space, the green sub-pixel can occupy a bottom right space, and the blue sub-pixels can occupy the top and bottom left spaces. Current flows through the openings 330 to activate the red sub-pixels or green sub-pixels or blue sub-pixels within each of the square unit pixels.

FIG. 4 is a schematic, perspective view 400 of the RGB pixel array where the third evaporation source is used from a fifth direction to create a fifth color pixel, according to one or more of the embodiments described herein.

The third evaporation source 362 is positioned at a side (direction or orientation E₃) of the array 301 such that ½ of each square unit pixel is shadowed. This results in a ½ area of each square unit pixel that is exposed. The exposed area 435 of each square unit pixel is configured to receive OLED material to create a fifth color pixel 460. In one example, the fifth color pixel 460 is blue. The result of positioning the third evaporation source 362 at the side of the square unit pixel is that a single blue sub-pixel is formed adjacent the red sub-pixel (the first color pixel 340) and the green sub-pixel (the second color pixel 350) because the exposed area 435 is ½ of each square unit pixel. The blue sub-pixel (the fifth color pixel 460) is thus twice the size of the first color pixel 340 and twice the size of the second color pixel 350. Of course, in other examples, the color of the larger pixel or sub-pixel may be red or green. The configuration of FIG. 4 is based on the deposition technique shown in FIGS. 1A and 2B.

Similarly to FIGS. 3A-3E, current flows through the openings 330 of the unit pixels, which permits a continuous current path through a cathode 970 of a sub-pixel circuit (FIGS. 9A-9F). The current flows to the cathode disposed along the sub-pixel circuit to the bus-bars 924. Thus, current is operable to flow through the sub-pixel circuit. The current also flows from the cathode to the OLED material and into metal layers (not shown) of the sub-pixel circuit. The current activates sub-pixels within the unit pixels.

Similarly to FIGS. 3A-3E, a portion of the first walls 310 and a portion of the second walls 312 can collectively form a pinwheel configuration 325. For example, wall portions 320 form the pinwheel configuration 325. The pinwheel configuration 325 includes two horizontal walls and two vertical walls. The two horizontal walls and the two vertical walls are separated from each other by the openings 330. The two horizontal walls do not contact the two vertical walls. The pinwheel configuration 325 defines a centrally disposed unit pixel with 3 sub-pixels. The array 301 can be divided to define a plurality of pinwheel configurations. As such, the pinwheel configuration 325 includes four walls or four dielectric walls separated by predefined openings or gaps between them to provide for uniform cathode current flow. The pinwheel configuration 325 can also be referred to as a pinwheel shaped self-mask.

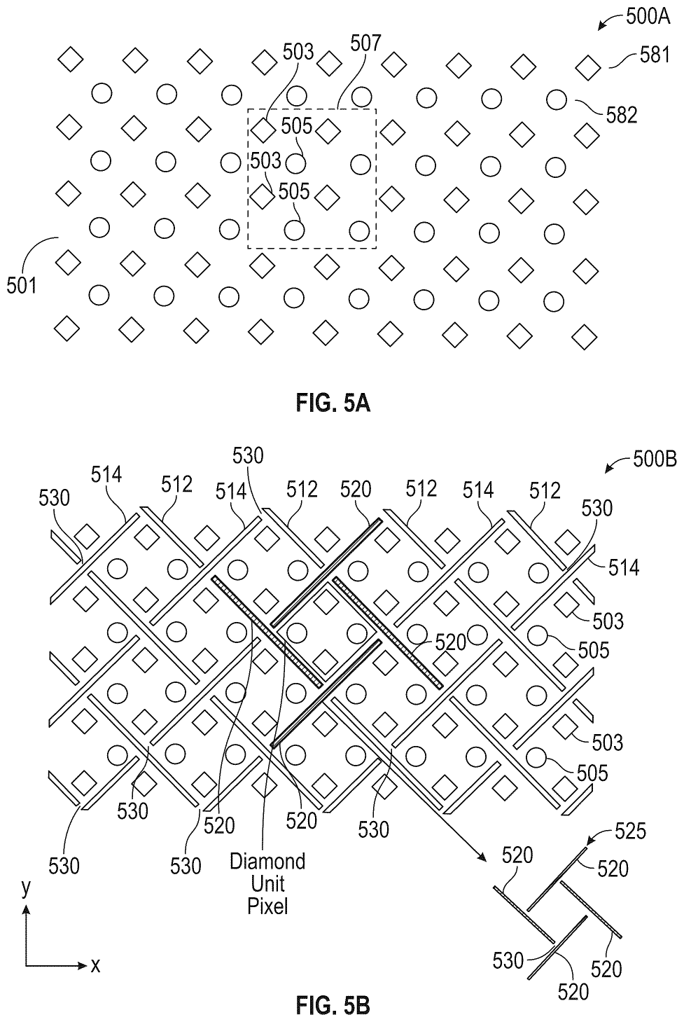

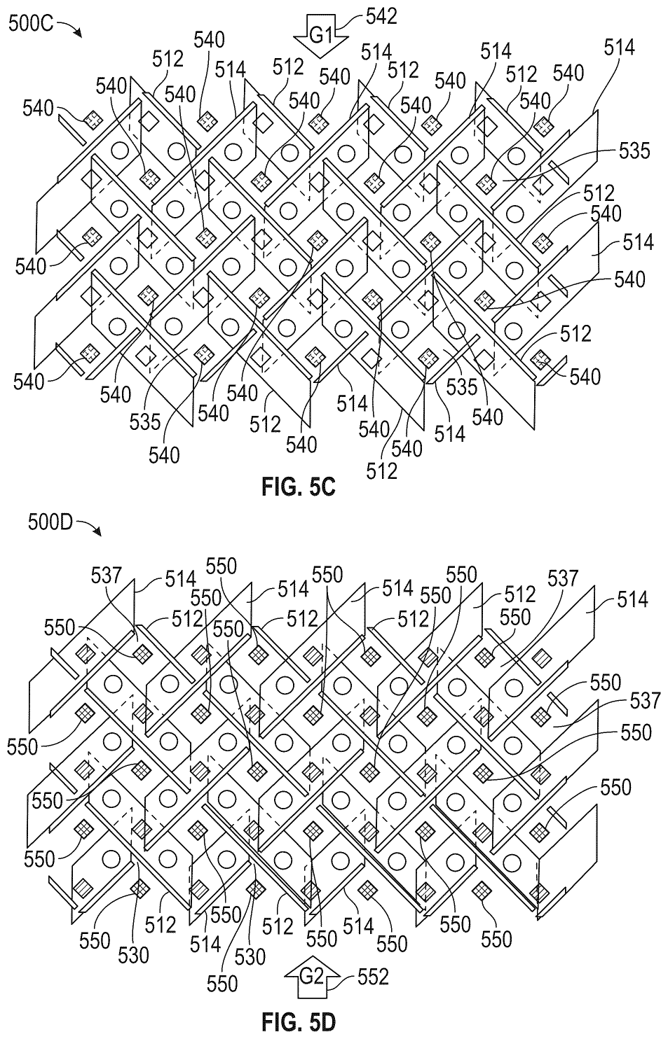

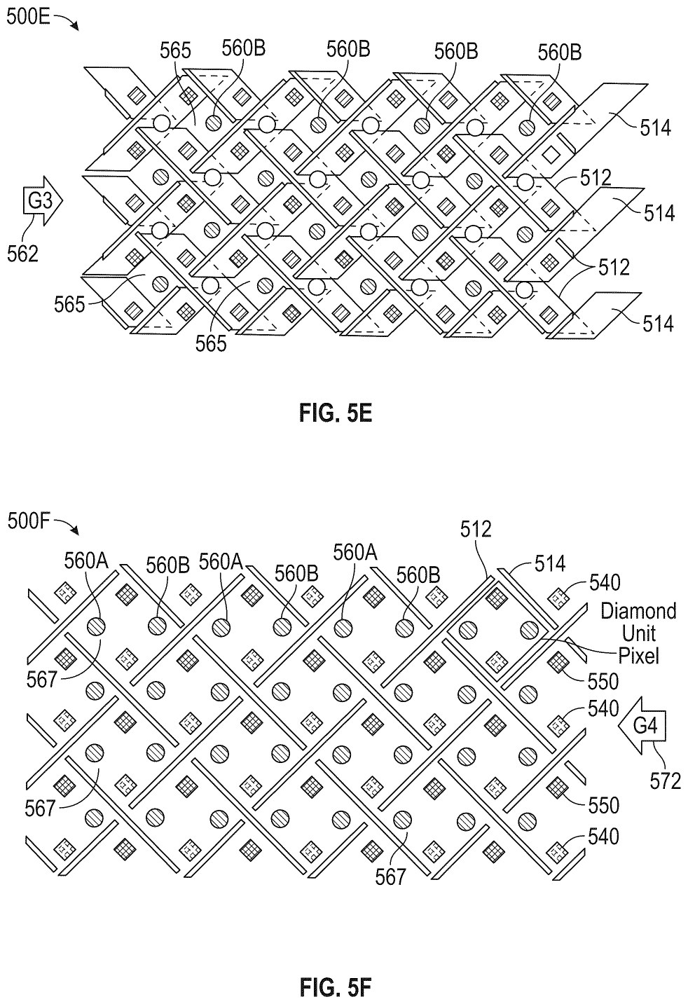

FIG. 5A is a schematic, top-view 500A of a PenTile diamond pixel array, according to one or more of the embodiments described herein.

The array 501 includes a plurality of pixels. The plurality of pixels includes first pixels 503 and second pixels 505. The first pixels 503 have a diamond shape and the second pixels 505 have a circular or oval shape. A PenTile matrix is a family of matrix schemes used in electronic device displays. PenTile matrices can be used in OLED or micro-OLED displays.

The array 501 is configured to be a rectangular array. The first row 581 of the array 501 includes the first pixels 503, which are diamond pixels. The second row 582 of the array 501 includes the second pixels 505, which are the circular or oval pixels. The first pixels 503 of the first row 581 are vertically offset from the second pixels 505 of the second row 582. Therefore, the first pixels 503 are vertically aligned within the array 501 and the second pixels 505 are vertically aligned within the array 501. As such, all the first pixels 503 are all vertically offset from all the second pixels 505. A square unit pixel 507 can include multiple first pixels 503 and multiple second pixels 505.

When constructing OLEDs or micro-OLEDs, one sub-pixel array commonly used is the PenTile array or PenTile matrix. FIGS. 5A-5F relate to a PenTile array, and, in particular, to a self-mask design for PenTile arrays.

FIG. 5B is a schematic, top-view 500B of the PenTile diamond pixel array where dielectric walls are formed to divide the PenTile diamond pixel array into multiple diamond unit pixels, according to one or more of the embodiments described herein.

The array 501 is divided into a plurality of unit pixels. The unit pixels have been rotated by 45 degrees compared to the unit pixels of FIGS. 3A-3E. The unit pixels are diamond shaped. Each unit pixel includes, e.g., 4 pixels or sub-pixels. The 4 sub-pixels are arranged in a diamond shaped array. The array 501 is divided by strategically placing walls or dielectric walls or self-mask walls adjacent the first pixels 503 and the second pixels 505. Two types of walls are placed or disposed or formed. The first walls 512 are at a 45 degree angle with respect to the x-axis of the XY graph and the second walls 514 are also at a 45 degree angle with respect to the x-axis of the XY graph. The first walls 512 form a 90 degree angle with the second walls 514 (or are perpendicular to each other). The first walls 512 are slanted or oblique or inclined or sloped with respect to the x-axis of the XY graph. Similarly, the second walls 514 are slanted or oblique or inclined or sloped with respect to the x-axis of the XY graph.

Each unit pixel includes two first pixels 503 and two second pixels 505. The two first pixels 503 are the diamond shaped pixels and are vertically aligned with respect to each other. The two second pixels 505 are the circular or oval shaped pixels and are horizontally aligned with respect to each other. The first two pixels 503 are vertically offset from the second two pixels 505. The first two pixels 503 occupy the top and bottom spaces of the unit pixel, whereas the second two pixels 505 occupy the side spaces of the unit pixel. The first two pixels 503 reside in the top and bottom corners of the diamond shaped unit pixel. The second two pixels 505 reside in the side corners of the diamond shaped unit pixel.

The first walls 512 and the second walls 514 do not contact or intersect each other. Openings 530 are formed at the ends of the first walls 512 and the second walls 514. The openings 530 can also be referred to as gaps. The openings 530 allow for current to flow through the unit pixels to activate the first pixels 503 and the second pixels 505. The first walls 512 and the second walls 514 may partially surround each unit pixel, leavings the openings 530 between adjacent walls.

Current flows through the openings 530 of the unit pixels, which permits a continuous current path through a cathode 970 of a sub-pixel circuit (FIGS. 9A-9F). The current flows to the cathode disposed along the sub-pixel circuit to the bus-bars 924. Thus, current is operable to flow through the sub-pixel circuit. The current also flows from the cathode to the OLED material and into metal layers (not shown) of the sub-pixel circuit. The current activates sub-pixels within the unit pixels.

A portion of the first walls 512 and a portion of the second walls 514 can collectively form a pinwheel configuration 525. For example, wall portions 520 form the pinwheel configuration 525. The pinwheel configuration 525 includes two first slanted walls parallel to each other and two second slanted walls parallel to each other. The wall portions 520 are separated from each other by the openings 530. The pinwheel configuration 525 defines a centrally disposed unit pixel with 4 sub-pixels. The array 501 can be divided to define a plurality of pinwheel configurations. As such, the pinwheel configuration 525 includes four walls or four dielectric walls separated by predefined openings or gaps between them to provide for uniform cathode current flow. The pinwheel configuration 525 can also be referred to as a pinwheel shaped self-mask. The pinwheel shaped self-mask of FIGS. 5B-5F are rotated by 45 degrees compared to the pinwheel shaped self-mask of FIGS. 3C-3E.

FIG. 5C is a schematic, perspective view 500C of the PenTile diamond pixel array where a first evaporation source is used from a first direction to create a first color pixel, according to one or more of the embodiments described herein.

The first evaporation source 542 is positioned at a top side (direction or orientation G₁) of the array 501 such that ¾ of each diamond unit pixel is shadowed. This results in a ¼ area of each diamond unit pixel that is exposed. The exposed area 535 of each diamond unit pixel is configured to receive OLED material to create a first color pixel 540. In one example, the first color pixel 540 is red. As such, one red sub-pixel is formed in each diamond unit pixel. Since there are multiple diamond unit pixels, there are multiple red sub-pixels within the array 501. Of course, in other examples, the color of the pixel may be green or blue.

A first portion of the red sub-pixels of each of the diamond unit pixels are horizontally aligned with respect to each other (in each row). A second portion of the red sub-pixels of each of the diamond unit pixels are vertically aligned with respect to each other (in each column). Each red sub-pixel is equally spaced apart with respect to adjacent red sub-pixels.

FIG. 5D is a schematic, perspective view 500D of the PenTile diamond pixel array where a second evaporation source is used from a second direction to create a second color pixel, according to one or more of the embodiments described herein.

The second evaporation source 552 is positioned at a bottom side (direction or orientation G₂) of the array 501 such that ¾ of each diamond unit pixel is shadowed. This results in a ¼ area of each diamond unit pixel that is exposed. The exposed area 537 of each diamond unit pixel is configured to receive OLED material to create a second color pixel 550. In one example, the second color pixel 550 is blue. As such, one blue sub-pixel is formed in each diamond unit pixel. Since there are multiple diamond unit pixels, there are multiple blue sub-pixels within the array 501. Of course, in other examples, the color of the pixel may be red or green.

The green sub-pixels of each of the square unit pixels are horizontally aligned with respect to each other. Further, the green sub-pixels of each of the square unit pixels are vertically aligned with respect to each other. Each green sub-pixel is equally spaced apart with respect to adjacent green sub-pixels.

A first portion of the blue sub-pixels of each of the diamond unit pixels are horizontally aligned with respect to each other (in each row). A second portion of the blue sub-pixels of each of the diamond unit pixels are vertically aligned with respect to each other (in each column). Each blue sub-pixel is equally spaced apart with respect to adjacent blue sub-pixels. The first portion of the blue sub-pixels (in each row) are horizontally aligned with the first portion of the red sub-pixels (in each row). The second portion of the blue sub-pixels (in each column) are vertically aligned with the second portion of the red sub-pixels (in each column).

FIG. 5E is a schematic, perspective view 500E of the PenTile diamond pixel array where a third evaporation source is used from a third direction to create a third color pixel, according to one or more of the embodiments described herein.

The third evaporation source 562 is positioned at a left side (direction or orientation G₃) of the array 501 such that ¾ of each diamond unit pixel is shadowed. This results in a ¼ area of each diamond unit pixel that is exposed. The exposed area 565 of each diamond unit pixel is configured to receive OLED material to create a third color pixel 560B. In one example, the third color pixel 560B is green. Since there are multiple diamond unit pixels, there are multiple green sub-pixels within the array 501. Of course, in other examples, the color of the pixel may be red or blue.

A first portion of the green sub-pixels of each of the diamond unit pixels are horizontally aligned with respect to each other (in each row). A second portion of the green sub-pixels of each of the diamond unit pixels are vertically aligned with respect to each other (in each column). Each green sub-pixel is equally spaced apart with respect to adjacent red sub-pixels. The third color pixel 560B can be formed at the right corner of the diamond unit pixel. Thus, at this point of the process 3 sub-pixels have been formed in the diamond unit pixel.

FIG. 5F is a schematic, perspective view 500F of the PenTile diamond pixel array where a fourth evaporation source is used from a fourth direction to create a fourth color pixel, according to one or more of the embodiments described herein.

The fourth evaporation source 572 is positioned at a right side (direction or orientation G₄) of the array 501 such that ¾ of each diamond unit pixel is shadowed. This results in a ¼ area of each diamond unit pixel that is exposed. The exposed area 567 of each diamond unit pixel is configured to receive OLED material to create a fourth color pixel 560A. In one example, the fourth color pixel 560A is also green. As such, two green sub-pixels are formed in each diamond unit pixel. Since there are multiple diamond unit pixels, there are multiple green sub-pixels within the array 501. Of course, in other examples, the color of the pixel may be red or blue.

A first portion of the green sub-pixels of each of the diamond unit pixels are horizontally aligned with respect to each other (in each row). A second portion of the green sub-pixels of each of the diamond unit pixels are vertically aligned with respect to each other (in each column). Some of the third color pixels 560B are horizontally aligned with some of the fourth color pixels 560A. The third color pixels 560B are vertically aligned with respect to each other. Also, the fourth color pixels 560A are vertically aligned with respect to each other. The third color pixels 560B are not vertically aligned with respect to any of the fourth color pixels 560A.

Each green sub-pixel is equally spaced apart with respect to adjacent red sub-pixels. The fourth color pixel 560A can be formed at the left corner of the diamond unit pixel. Thus, all 4 sub-pixels have been formed in the diamond unit pixel. The PenTile sub-pixel scheme has twice as many green sub-pixels as there are blue and red sub-pixels. The green sub-pixels are circular or oval. In one example, the green sub-pixels are smaller than the blue and red oval sub-pixels. The green sub-pixels are more efficient and longer lasting OLED emitters and can thus have a smaller size compared to the red and blue sub-pixels.

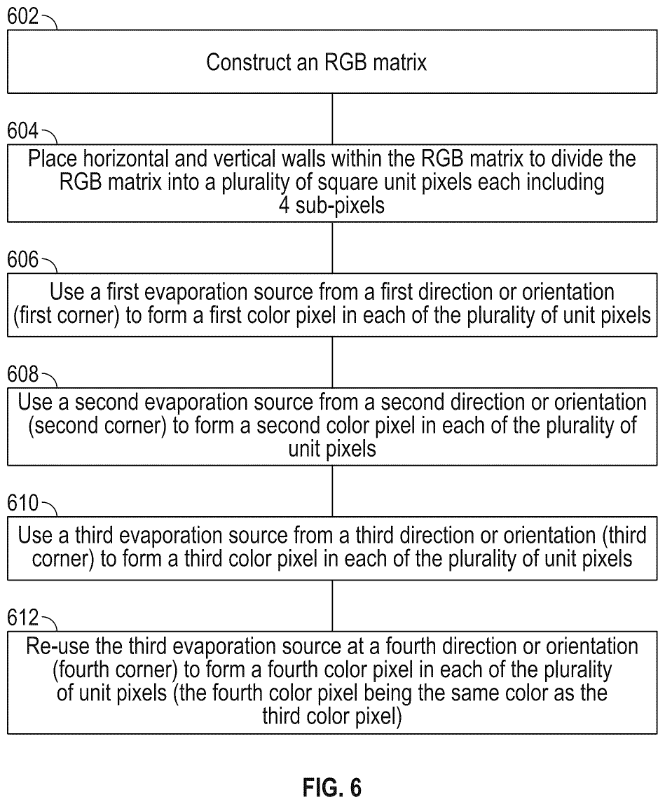

FIG. 6 is a method for using walls to divide an RGB matrix into square unit pixels each having 4 sub-pixels, according to one or more of the embodiments described herein.

In block 602, an RGB matrix is constructed.

In block 604, horizontal and vertical walls are placed or disposed of formed within the RGB matrix to divide the RGB matrix into a plurality of square unit pixels each including 4 sub-pixels.

In block 606, a first evaporation source is used from a first direction or orientation (first corner) to form a first color pixel in each of the plurality of unit pixels.

In block 608, a second evaporation source is used from a second direction or orientation (second corner) to form a second color pixel in each of the plurality of unit pixels.

In block 610, a third evaporation source is used from a third direction or orientation (third corner) to form a third color pixel in each of the plurality of unit pixels.

In block 612, the third evaporation source is re-used at a fourth direction or orientation (fourth corner) to form a fourth color pixel in each of the plurality of unit pixels (the fourth color pixel being the same color as the third color pixel).

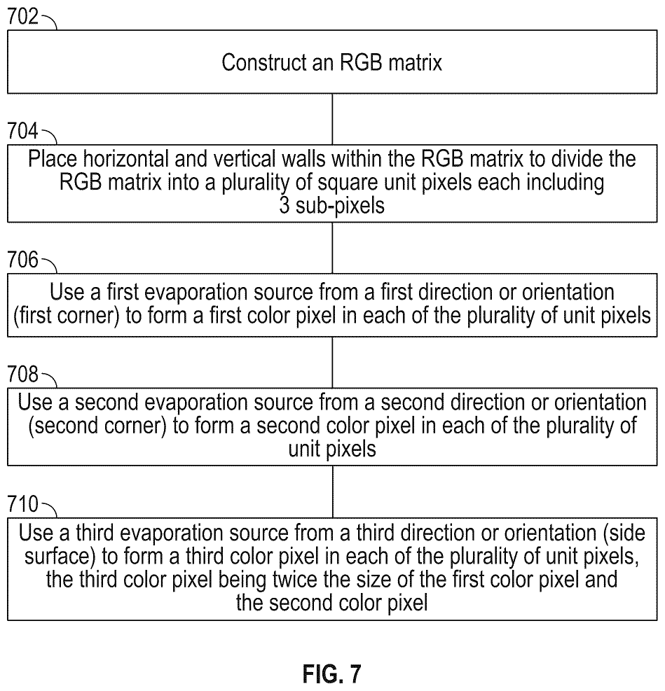

FIG. 7 is a method for using walls to divide an RGB matrix into square unit pixels each having 3 sub-pixels according to one or more of the embodiments described herein.

In block 702, an RGB matrix is constructed.

In block 704, horizontal and vertical walls are placed or disposed or formed within the RGB matrix to divide the RGB matrix into a plurality of square unit pixels each including 3 sub-pixels.

In block 706, a first evaporation source is used from a first direction or orientation (first corner) to form a first color pixel in each of the plurality of unit pixels.

In block 708, a second evaporation source is used from a second direction or orientation (second corner) to form a second color pixel in each of the plurality of unit pixels.

In block 710, a third evaporation source is used from a third direction or orientation (side surface) to form a third color pixel in each of the plurality of unit pixels, the third color pixel being twice the size of the first color pixel and the second color pixel.

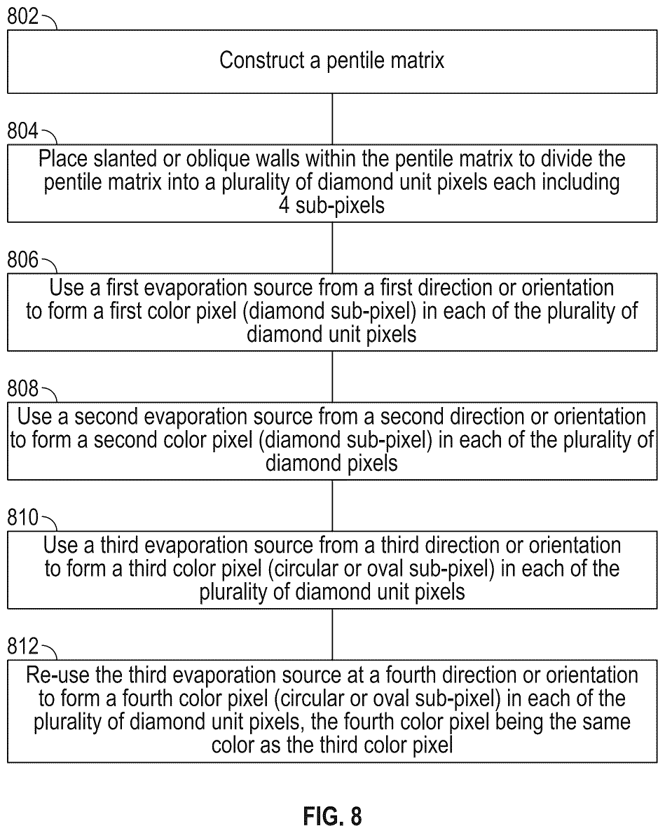

FIG. 8 is a method for using walls to divide a PenTile matrix into diamond unit pixels each having 4 sub-pixels, where two of the sub-pixels are diamond shaped, according to one or more of the embodiments described herein.

In block 802, a PenTile matrix is constructed.

In block 804, slanted or oblique walls are placed or disposed or formed within the PenTile matrix to divide the PenTile matrix into a plurality of diamond unit pixels each including 4 sub-pixels.

In block 806, a first evaporation source is used from a first direction or orientation to form a first color pixel (diamond sub-pixel) in each of the plurality of diamond unit pixels.

In block 808, a second evaporation source is used from a second direction or orientation to form a second color pixel (diamond sub-pixel) in each of the plurality of diamond unit pixels.

In block 810, a third evaporation source is used from a third direction or orientation to form a third color pixel (circular or oval sub-pixel) in each of the plurality of diamond unit pixels.

In block 812, the third evaporation source is re-used at a fourth direction or orientation to form a fourth color pixel (circular or oval sub-pixel) in each of the plurality of diamond unit pixels, the fourth color pixel being the same color as the third color pixel.

FIGS. 9A-9F illustrate a cross-sectional view of a sub-pixel circuit for the RGB pixel array, according to one or more of the embodiments described herein.

In FIG. 9A, cross-sectional view 900A depicts a plurality of sub-pixels 902 formed over a substrate 927. The plurality of sub-pixels can be, e.g., thin-film transistors (TFTs) 904 formed within a TFT layer 925. A unit pixel 910 is further illustrated. A unit pixel includes four sub-pixels. However, the cross-sectional view taken along A-A of FIG. 3C extends along two sub-pixels of each unit pixel. As such, the two-sub pixels have been designated as the unit pixel 910 for illustration purposes. A pixel definition layer (PDL) 920 is formed using, e.g., a PECVD process. The PDL 920 is a patterned insulating layer with openings that define areas where the organic emissive materials (red, green, blue) are deposited. These openings correspond to the individual OLED pixels. The PDL 920 serves as a structural and functional interface for the deposition of the organic layers. Further, bus-bars 924 are formed adjacent the sub-pixels 902 and a self-mask 922 is formed over the sub-pixels 902. The bus-bars 924 may be referred to as bus lines or power bus bars. The bus-bars 924 help distribute electrical power uniformly across the display panel. Stated differently, the bus-bars 924 help balance the electrical load across the OLED display, distributing current evenly and preventing power loss.

The substrate 927 may include, but is not limited to, silicon (Si), silicon dioxide (SiO₂), fused silica, quartz, silicon carbide (SiC), germanium (Ge), silicon germanium (SiGe), indium phosphide (InP), gallium arsenide (GaAs), gallium nitride (GaN), silicon nitride (Si₃N₄), or sapphire containing materials.

In some embodiments, the PDL 920 includes an inorganic insulator material. The inorganic insulator material may include, but is not limited to, SiO₂, Si₃N₄, silicon oxynitride (Si₂N₂O), magnesium fluoride (MgF₂), or combinations thereof.

In FIG. 9B, cross-sectional view 900B depicts common layer deposition. In particular, a hole injection layer (HIL) 930 is formed over the sub-pixels 902 and adjacent a lower section of the self-mask 922.

In FIG. 9C, cross-sectional view 9000 depicts forming a red emission layer (EML) 940 and a green EML 950. The red EML 940 is formed over a first sub-pixel and the green EML 950 is formed over a second sub-pixel of the unit pixel 910.

In FIG. 9D, cross-sectional view 900D depicts common layer deposition. In particular, an electron transport layer (ETL) or an electron injection layer (EIL) 960 is deposited over the red EML 940 and the green EML 950. The ETL or EIL 960 directly contacts the red EML 940 and the green EML 950.

In FIG. 9E, cross-sectional view 900E depicts a cathode 970 formed over the structure. The current flows to the cathode 970 disposed along the sub-pixel circuit to the bus-bars 924. Thus, current is operable to flow through the sub-pixel circuit. The current also flows from the cathode 970 to the OLED material and into metal layers (not shown) of the sub-pixel circuit. Each cathode electrode 972 is connected through the openings 330.

In FIG. 9F, cross-sectional view 900F depicts a thin film encapsulation process. The thin film encapsulation process includes depositing a first thin film 980 via, e.g., a chemical vapor deposition (CVD) process, a monomer 982, and second thin film 984 also via a CVD process. The second thin film 984 can be planarized, via chemical mechanical polishing (CMP), such that the top surface of the second thin film 984 is flush with the top surface of the self-mask 922.

A similar process described in FIGS. 9A-9F can be performed for constructing a sub-pixel circuit for a PenTile array.

In summary, self-mask designs are presented for square unit pixels and for PenTile unit pixels. When constructing OLEDs or micro-OLEDs, one sub-pixel array commonly used is the RGB array or RGB matrix or RGB stripe. One example embodiment relates to an RGB array, and, in particular, to a self-mask design for RGB arrays. When constructing OLEDs or micro-OLEDs, another sub-pixel array commonly used is the PenTile array or PenTile matrix. Another example embodiment relates to a PenTile array, and, in particular, to a self-mask design for PenTile arrays. Each unit pixel, whether square or diamond, includes a number of pixels or sub-pixels. In one example, each unit pixel, whether square or diamond, includes 4 sub-pixels. The square unit pixels each include 4 circular or oval sub-pixels and the diamond unit pixels each include 2 diamond sub-pixels and 2 circular or oval sub-pixels. Each sub-pixel may have the OLED material configured to emit a red, green, blue or other color light when energized. Each unit pixel or unit cell may be partially surrounded by a number of walls, the walls partially separating adjacent unit pixels and forming a number of openings or gaps between adjacent unit pixels. The shape and/or curves of the walls may be manipulated to enable the formation of desired unit pixels. In some embodiments, the one or more walls may include walls having different shapes and/or curves. The openings or gaps between adjacent walls allow current to pass through the unit pixels. In addition, the unit pixels may be formed using oblique deposition for EML deposition for red, green, and blue colors. The deposition process may include an evaporation process. The angle of deposition used during the deposition of the OLED material may be carefully controlled during formation of the sub-pixels in the unit pixels. Controlling the angle of deposition results in a more stable open area formation and shadow area formation.

While the foregoing is directed to embodiments of the present disclosure, other and further embodiments of the disclosure may be devised without departing from the basic scope thereof, and the scope thereof is determined by the claims that follow.

What is claimed is:

1. A method comprising:
constructing an RGB matrix;
forming dielectrics which divide the RGB matrix into a plurality of square unit pixels;
forming a first color pixel in each of the plurality of square unit pixels by using a first evaporation source;
forming a second color pixel in each of the plurality of square unit pixels by using a second evaporation source; and
forming a third color pixel in each of the plurality of square unit pixels by using a third evaporation source.

2. The method of claim 1, wherein the dielectrics define horizontal walls and vertical walls.

3. The method of claim 1, wherein each square unit pixel includes four sub-pixels.

4. The method of claim 1, wherein the first evaporation source is actuated from a first corner of the RGB matrix.

5. The method of claim 4, wherein the second evaporation source is actuated from a second corner of the RGB matrix, the second corner being different than the first corner.

6. The method of claim 5, wherein the third evaporation source is actuated from a third corner of the RGB matrix to form the third color pixel, the third corner being different than the first corner and the second corner.

7. The method of claim 6, wherein the third evaporation source is actuated from a fourth corner of the RGB matrix to form a fourth color pixel, the fourth corner being different than the first corner, the second corner, and the third corner.

8. The method of claim 1, wherein the dielectrics define dielectric walls separated from each other by openings and wherein the openings allow current to pass therethrough to activate the first color pixel, the second color pixel, and the third color pixel of each square unit pixel.

9. The method of claim 1, wherein a portion of the dielectrics form multiple pinwheel shapes within the RGB matrix and wherein each of the multiple pinwheel shapes includes two vertical dielectric walls and two horizontal dielectric walls.

10. The method of claim 1, further comprising forming a fourth color pixel in each of the plurality of square unit pixels by using the third evaporation source, the fourth color pixel being a same color as the third color pixel.

11. The method of claim 1, further comprising forming the third color pixel in each of the plurality of square unit pixels by using the third evaporation source at a side of the RGB matrix such that the third color pixel is twice a size of the first color pixel and twice a size of the second color pixel.

12. A sub-pixel circuit, comprising:
a plurality of square unit pixels, each square unit pixel including dielectric walls disposed therearound to form multiple pinwheel shapes;
a first color pixel formed in each square unit pixel using a first evaporation source;
a second color pixel formed in each square unit pixel using a second evaporation source; and
a third color pixel formed in each square unit pixel using a third evaporation source.

13. The sub-pixel circuit of claim 12, wherein the dielectric walls are separated from each other by openings, wherein the openings allow current to pass therethrough to activate the first color pixel, the second color pixel, and the third color pixel.

14. The sub-pixel circuit of claim 12, wherein each square unit pixel includes four sub-pixels.

15. The sub-pixel circuit of claim 12, wherein each square unit pixel includes three sub-pixels.

16. The sub-pixel circuit of claim 12, wherein each of the multiple pinwheel shapes includes two vertical dielectric walls and two horizontal dielectric walls.

17. A method comprising:
constructing a PenTile matrix;
forming dielectrics which divide the PenTile matrix into a plurality of diamond unit pixels;
forming a first color pixel in each of the plurality of diamond unit pixels by using a first evaporation source;
forming a second color pixel in each of the plurality of diamond unit pixels by using a second evaporation source;
forming a third color pixel in each of the plurality of diamond unit pixels by using a third evaporation source; and
forming a fourth color pixel in each of the plurality of diamond unit pixels by using the third evaporation source, the fourth color pixel being a same color as the third color pixel.

18. The method of claim 17, wherein each diamond unit pixel includes four sub-pixels, two sub-pixels being diamond shaped and two sub-pixels being circular shaped.

19. The method of claim 17, wherein the dielectrics are separated from each other by openings, wherein the openings allow current to pass therethrough to activate the first color pixel, the second color pixel, the third color pixel, and the fourth color pixel.

20. The method of claim 17, wherein a portion of the dielectrics form multiple pinwheel shapes within the PenTile matrix.
